(19) United States
(12) Patent Application Publication
(10) Pub. No.: US 2025/0085465 A1
(43) Pub. Date: Mar. 13, 2025

(54) POLARIZING MEMBER AND DISPLAY DEVICE INCLUDING THE SAME

(71) Applicant: Samsung Display Co., LTD., Yongin-si (KR)

(72) Inventors: Beong Hun BEON, Yongin-si (KR); Duk Jin LEE, Yongin-si (KR); Woo Suk JUNG, Yongin-si (KR)

(21) Appl. No.: 18/673,973

(22) Filed: May 24, 2024

(30) Foreign Application Priority Data
Sep. 12, 2023 (KR) 10-2023-0121070

(51) Int. Cl. G02B 5/30; G02B 1/14; H10K 59/40; H10K 59/80

(52) U.S. Cl. CPC G02B 5/3016; G02B 1/14; H10K 59/40; H10K 59/873; H10K 59/8791

(57) ABSTRACT

A polarizing member includes a polarizer including an absorption axis and a transmission axis that intersect each other, a first retarder disposed under the polarizer, a second retarder disposed under the first retarder; and a third retarder disposed on the polarizer, where an in-plane retardation value of the third retarder ranges from approximately 37.5 nanometers (nm) to approximately 237.5 nm, and where an angle between a retardation axis of the third retarder and the transmission axis of the polarizer ranges from approximately 15 degrees (°) to approximately 75°.

This application claims priority to Korean Patent Application No. filed on 10-2023-0121070, filed on Sep. 12, 2023, and all the benefits accruing therefrom under 35 U.S.C. § 119, the content of which in its entirety is herein incorporated by reference.

### BACKGROUND

### 1. Field

The disclosure relates to a polarizing member and a display device including the same.

### 2. Description of the Related Art

As the information-oriented society evolves, various demands for display devices are also increasing. A display device may include a flat display panel such as a liquid-crystal display panel, an organic light-emitting display panel and an inorganic light-emitting display panel.

A display device may include an optical film, such as a polarizing member, disposed on a display panel in order to prevent deterioration of visibility due to external light. The optical film may prevent external light incident on the display device from being reflected off the display panel.

### SUMMARY

Features of the disclosure provide a polarizing member that may reduce reflection of external light, may improve visibility of polarized sunglasses, and may improve reliability, and a display device including the same.

It should be noted that features of the disclosure are not limited to the above-mentioned feature; and other features of the disclosure will be apparent to those skilled in the art from the following descriptions.

In an embodiment of the disclosure, a polarizing member includes a polarizer including an absorption axis and a transmission axis that intersect each other, a first retarder disposed under the polarizer, a second retarder disposed under the first retarder; and a third retarder disposed on the polarizer, where an in-plane retardation value of the third retarder ranges from approximately 37.5 nanometers (nm) to approximately 237.5 nm, and where an angle between a retardation axis of the third retarder and the transmission axis of the polarizer ranges from approximately 15 degrees (°) to approximately 75°.

In an embodiment, the third retarder may include nematic liquid crystals of a rod shape.

In an embodiment, the third retarder may include a λ/4 retarder.

In an embodiment, the first retarder may include a λ/2 retarder, and the second retarder includes a λ/4 retarder.

In an embodiment, the first retarder may include a λ/2 retarder, and the second retarder includes a positive C-plate.

In an embodiment, the polarizing member may further include a first protective film disposed between the polarizer and the first retarder, where the first protective film includes an acrylic resin film, a polyester resin film, a cellulose resin film, or a polyolefin resin film.

In an embodiment, the polarizing member may further include a second protective film disposed between the polarizer and the third retarder.

In an embodiment, the polarizing member may further include a protective film disposed on the third retarder.

In an embodiment, the polarizing member may further include a hard coating layer disposed on the protective film, where the hard coating layer may include (meth)acrylate.

In an embodiment, the polarizing member may further include a first protective film disposed between the polarizer and the third retarder, where the first protective film may include an acrylic resin film, a polyester resin film, a cellulose resin film, or a polyolefin resin film.

In an embodiment, the polarizing member may further include a hard coating layer disposed on the third retarder, where the hard coating layer includes (meth)acrylate.

In an embodiment, the polarizing member may further include a first protective film disposed between the polarizer and the first retarder, where the first protective film includes an acrylic resin film, a polyester resin film, a cellulose resin film, or a polyolefin resin film.

In an embodiment, the polarizing member may further include a second protective film disposed between the polarizer and the third retarder.

In an embodiment of the disclosure, a display device includes a display panel, and a polarizing member disposed on the display panel, where the polarizing member includes a polarizer having an absorption axis and a transmission axis that intersect each other, a first retarder disposed under the polarizer, a second retarder disposed under the first retarder, and a third retarder disposed on the polarizer, where an in-plane retardation value of the third retarder ranges from approximately 37.5 nm to approximately 237.5 nm, and where an angle between a retardation axis of the third retarder and the transmission axis of the polarizer ranges from approximately 15° to approximately 75°.

In an embodiment, the display panel may include a pixel electrode disposed on a substrate, a light-emitting layer disposed on the pixel electrode, and a common electrode disposed on the light-emitting layer.

In an embodiment, the display panel may include an encapsulation layer disposed on the common electrode, and a touch sensor disposed on the encapsulation layer.

In an embodiment, the display device may further include a cover window disposed on the polarizing member.

In an embodiment, the third retarder may include nematic liquid crystals of a rod shape.

In an embodiment, the third retarder may include a λ/4 retarder.

In an embodiment, the first retarder may include a λ/2 retarder, and the second retarder may include a λ/4 retarder.

In an embodiment of the disclosure, a polarization member may convert light linearly polarized in a polarizer into elliptically polarized light in a third retarder in a display device, so that a user wearing polarized sunglasses may view images on a display panel.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is an exploded, perspective view of an embodiment of a display device according to the disclosure.

FIG. 2 is a side view showing an embodiment of a display device according to the disclosure.

FIG. 3 is a view showing a layout of an embodiment of a display area of a display panel according to the disclosure.

FIG. 4 is a cross-sectional view showing an embodiment of the display panel taken along line B-B′ of FIG. 3.

FIG. 5 is an exploded perspective view of an embodiment of the polarizing member of FIG. 4.

FIG. 6 is a view showing the slow axis of the third retardation layer and the transmission axis and absorption axis of the polarizer.

FIG. 7 is a cross-sectional view showing an embodiment of a polarizing member and polarization of light.

FIG. 8 is an exploded, perspective view showing another embodiment of a polarizing member.

FIG. 9 is an exploded perspective view showing another embodiment of a polarizing member.

FIG. 10 is an exploded perspective view showing another embodiment of a polarizing member.

FIG. 11 is an exploded perspective view showing another embodiment of a polarizing member.

FIG. 12 is an exploded perspective view showing another embodiment of a polarizing member.

FIG. 13 is an exploded perspective view showing another embodiment of a polarizing member.

FIG. 14 is an exploded perspective view showing another embodiment of a polarizing member.

FIG. 15 is an exploded perspective view showing another embodiment of a polarizing member.

FIG. 16 is a graph showing temperature change over time as conditions for reliability evaluation.

FIG. 17 is a graph showing results of reliability evaluation on the polarizing members.

FIG. 18 is a view showing locations where cracks in third retarders of the polarizing members were observed.

FIG. 19 is an optical image of the camera hole after 150 cycles of reliability evaluation were conducted in the polarizing member according to Embodiment 1.

FIG. 20 is an optical image of the camera hole after 150 cycles of reliability evaluation were conducted in the polarizing member according to Embodiment 2.

FIG. 21 is an optical image of the camera hole after 150 cycles of reliability evaluation were conducted in the polarizing member according to Comparative Example.

FIG. 22 is an optical image of the camera hole after 500 cycles of reliability evaluation were conducted in the polarizing member according to Embodiment 1.

FIG. 23 is an optical image of the camera hole after 500 cycles of reliability evaluation were conducted in the polarizing member according to Embodiment 2.

FIG. 24 is an optical image of the camera hole after 500 cycles of reliability evaluation were conducted in the polarizing member according to Comparative Example.

FIG. 25 is an SEM image of the camera hole after 500 cycles of reliability evaluation were conducted in the polarizing member according to Embodiment 1.

FIG. 26 is an SEM image of the camera hole after 500 cycles of reliability evaluation were conducted in the polarizing member according to Comparative Example.

FIG. 27 is an enlarged image of the image of FIG. 26.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on another layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second clement could also be termed the first element.

Each of the features of the various embodiments of the disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the disclosure will be described with reference to the accompanying drawings.

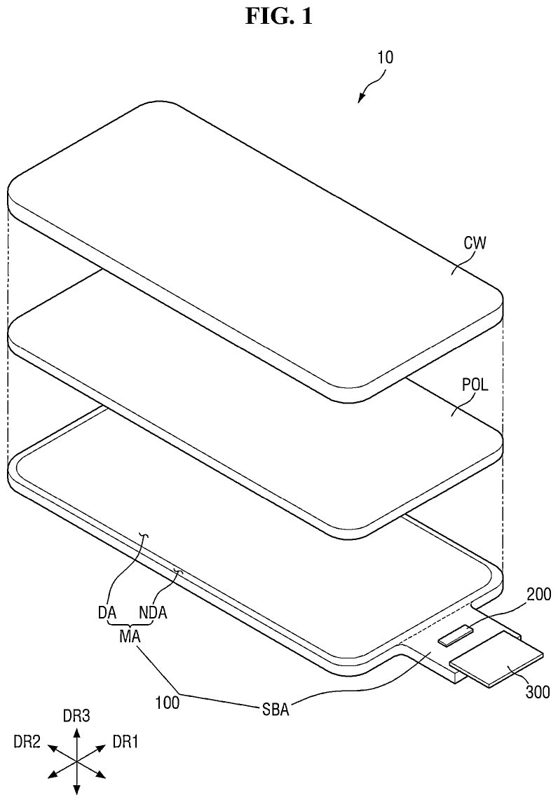

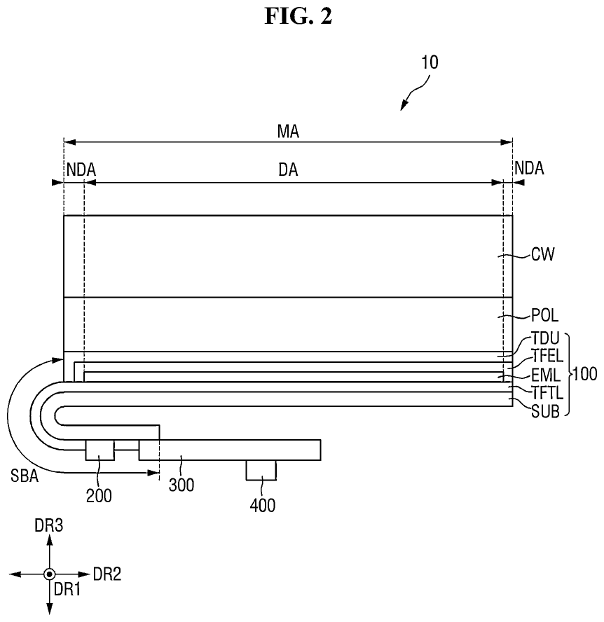

FIG. 1 is an exploded, perspective view of an embodiment of a display device according to the disclosure. FIG. 2 is a side view showing an embodiment of a display device according to the disclosure.

Referring to FIGS. 1 to 2, a display device 10 in an embodiment of the disclosure is for displaying moving images or still images. The display device 10 may be used as the display screen of portable electronic devices such as a mobile phone, a smart phone, a tablet personal computer (“PC”), a smart watch, a watch phone, a mobile communications terminal, an electronic notebook, an electronic book, a portable multimedia player (“PMP”), a navigation device and a ultra mobile PC (“UMPC”), as well as the display screen of various products such as a television, a notebook, a monitor, a billboard and the Internet of Things device.

In an embodiment of the disclosure, the display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described in an embodiment of the display device 10. It is, however, to be understood that embodiments of the disclosure are not limited thereto.

The display device 10 includes a display panel 100, a display driver circuit 200 and a circuit board 300.

The display panel 100 may be formed in a quadrangular plane, e.g., rectangular plane having shorter sides in the first direction DR1 and longer sides in the second direction DR2 intersecting the first direction DR1. In addition, the display panel 100 may have a thickness in the third direction DR3 that intersects the first direction DR1 and the second direction DR2. Each of the corners where the shorter side in the first direction DR1 meets the longer side in the second direction DR2 may be rounded with a predetermined curvature or may be a right angle. The shape of the display panel 100 when viewed from the top is not limited to a quadrangular shape, but may be formed in a different polygonal shape, a circular shape, or an elliptical shape. The display panel 100 may be formed flat, but the disclosure is not limited thereto. In an embodiment, the display panel 100 may be formed at left and right ends, and may include a curved portion having a constant curvature or a varying curvature, for example. In addition, the display panel 100 may be flexible so that it may be curved, bent, folded or rolled.

A substrate SUB of the display panel 100 may include a main area MA and a subsidiary area SBA.

The main area MA may include a display area DA where images are displayed, and a non-display area NDA around the display area DA. The display area DA may occupy most of the main area MA. The display area DA may be disposed at the center of the main area MR. The non-display area NDA may be disposed adjacent to the display area DA. The non-display area NDA may be disposed on the outer side of the display area DA. The non-display area NDA may surround the display area DA. The non-display area NDA may be defined as the border of the display panel 100.

The subsidiary area SBA may be extended from one side of the main area MA in the second direction DR2. The length of the subsidiary area SBA in the second direction DR2 may be smaller than the length of the main area MA in the second direction DR2. The length of the subsidiary area SBA in the first direction DR1 may be substantially less than the length of the main area MA in the first direction DR1 or may be substantially equal to it. The sub-area SBA may be bent and may be disposed under the display panel 100. In this instance, the subsidiary area SBA may overlap with the main area MA in the third direction DR3.

The display driver circuit 200 may generate signals and voltages for driving the display panel 100. The display driver circuit 200 may be implemented as an integrated circuit (“IC”) and may be attached to the subsidiary area SBA of the display panel 100 by a chip on glass (“COG”) technique, a chip on plastic (“COP”) technique, or an ultrasonic bonding. In an alternative embodiment, the display driver circuit 200 may be attached on the circuit board 300 by the chip-on-film (“COF”) technique.

The circuit board 300 may be attached to one end of the subsidiary area SBA of the display panel 100. Accordingly, the circuit board 300 may be electrically connected to the display panel 100 and the display driver circuit 200. The display panel 100 and the display driver circuit 200 may receive digital video data, timing signals, and driving voltages through the circuit board 300. The circuit board 300 may be a flexible printed circuit board, a printed circuit board, or a flexible film such as a chip on film.

The touch driver circuit 400 may be disposed on the circuit board 300. The touch driver circuit 400 may be implemented as an IC and may be attached on the circuit board 300.

The touch driver circuit 400 may be electrically connected to a plurality of driving electrodes and a plurality of sensing electrodes of the touch detecting unit (also referred to as a touch sensor) TDU. The touch driver circuit 400 may apply a touch driving signal to a plurality of driving electrodes, and may sense a touch detection signal, e.g., a change in mutual capacitance, of each of a plurality of touch nodes a plurality of sensing electrodes. The touch driver circuit 400 may determine whether there is a user's touch or near proximity, based on the touch sensing signal of each of the plurality of touch nodes. A user's touch refers to that an object such as the user's finger or a pen is brought into contact with the front surface of the display device 10 disposed on the touch detecting unit TDU. A user's near proximity refers to that an object such as the user's finger and a pen is hovering over the front of the display device 10. In an embodiment, the display device 10 may further include a polarizing member POL and a cover window CW, which will be described in detail later.

As shown in FIG. 2, the display panel 100 may include a substrate SUB, a thin-film transistor layer TFTL, an emission material layer EML, an encapsulation layer TFEL, and a touch detecting unit TDU.

The substrate SUB may include or consist of an insulating material such as a polymer resin. In an embodiment, the substrate SUB may include or consist of polyimide, for example. The substrate SUB may be a flexible substrate that may be bent, folded, or rolled.

The thin-film transistor layer TFTL may be disposed on the substrate SUB. The thin-film transistor layer TFTL may be disposed in the main area MA and the subsidiary area SBA. The thin-film transistor layer TFTL includes thin-film transistors.

The emission material layer EML may be disposed on the thin-film transistor layer TFTL. The emission material layer EML may be disposed in the display area DA of the main area MA. The emission material layer EML includes light-emitting elements disposed in emission areas.

The encapsulation layer TFEL may be disposed on the emission material layer EML. The encapsulation layer TFEL may be disposed in the display area DA and the non-display area NDA of the main area MA. The encapsulation layer TFEL includes at least one inorganic film and at least one organic film for encapsulating the emission material layer.

The touch detecting unit TDU may be disposed on the encapsulation layer TFEL. The touch detecting unit TDU may be disposed in the display area DA and the non-display area NDA of the main area MA. The touch detecting unit TDU may sense a touch of a person or an object using sensor electrodes.

The polarizing member POL may be disposed on the touch detecting unit of the display panel 100. The polarizing member POL may be a feature that prevents external light from being reflected off the display panel 100 to deteriorate the visibility of the images displayed by the display panel 100. The polarizing member POL may be attached to the display panel 100 using a transparent adhesive such as a pressure sensitive adhesive (“PSA”), an optically clear adhesive *“OCA”) and an optically clear resin (“OCR”).

The cover window CW may be disposed on the polarizing member POL to protect the upper portion of the display panel 100. The cover window CW may be attached on the polarizing member POL by a transparent adhesive member such as an OCA film and an OCR. The cover window CW may be either an inorganic material such as glass or an organic material such as plastic and polymer material. In another embodiment, the cover window CW may be eliminated. In this instance, the polarizing member POL may include a hard coating layer or a surface treatment layer disposed at the top.

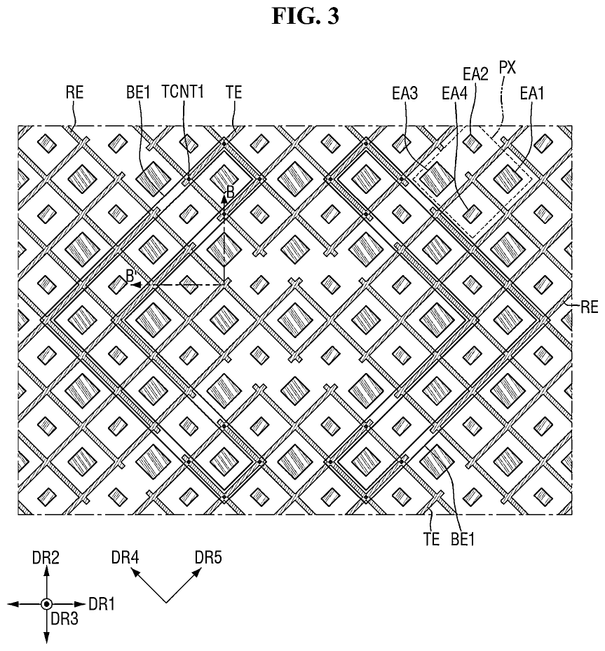

FIG. 3 is a view showing a layout of an embodiment of a display area of a display panel according to the disclosure. FIG. 3 shows the emission areas EA1, EA2, EA3 and EA4 of the emission material layer EML and the touch electrodes TE and RE of the touch detecting unit TDU. FIG. 3 shows an embodiment of touch nodes that are intersections of the driving electrodes TE and the sensing electrodes RE among the touch electrodes TE and RE.

The display area DA of the display panel 100 may include a plurality of pixels PX. Each of the pixels PX may include a first emission area EA1 of a first sub-pixel that emits light of a first color, a second emission area EA2 of a second sub-pixel that emits light of a second color, a third emission area EA3 of a third sub-pixel that emits light of a third color, and a fourth emission area EA4 of a fourth sub-pixel that emits light of the second color. In an embodiment, the light of the first color may be light of a red wavelength range, the light of the second color may be light of a green wavelength range, and the light of the third color may be light of a blue wavelength range, for example. The light of the red wavelength range may be defined as light with the wavelength of approximately 650 nanometers (nm), the light of the green wavelength range may be defined as light with the wavelength of approximately 550 nm, and the light of the blue wavelength range may be defined as light with the wavelength of approximately 450 nm. It should be understood, however, that the disclosure is not limited thereto.

In each of the pixels PX, the first emission area EA1 and second emission area EA2 may be adjacent to each other in a fourth direction DR4, and the third emission area EA3 and the fourth emission area EA4 may be adjacent to each other in the fourth direction DR4. In each of the pixels PX, the first emission area EA1 and fourth emission area EA4 may be adjacent to each other in a fifth direction DR5, and the second emission area EA2 and the third emission area EA3 may be adjacent to each other in the fifth direction DR5.

Each of the first emission area EA1, the second emission area EA2, the third emission area EA3 and the fourth emission area EA4 may have, but is not limited to, a diamond or a quadrangular shape, e.g., rectangular shape when viewed from the top. Each of the first emission area EA1, the second emission area EA2, the third emission area EA3 and the fourth emission area EA4 may have other polygonal shape than a quadrangular shape, a circular shape, or an elliptical shape when viewed from the top. In addition, although the third emission area EA3 is the largest while the second emission area EA2 and the fourth emission area EA4 are the smallest in the example shown in FIG. 3, the disclosure is not limited thereto.

The second emission areas EA2 and the fourth emission areas EA4 may be arranged in odd rows. The second emission areas EA2 and the fourth emission areas EA4 may be arranged side by side in each of the odd rows in the first direction DR1. The second emission areas EA2 and the fourth emission areas EA4 may be arranged alternately in odd rows. Each of the second emission areas EA2 may have shorter sides in the fourth direction DR4 and longer sides in the fifth direction DR5, while each of the fourth emission areas EA4 may have longer sides in the fourth direction DR4 and shorter sides in the fifth direction DR5. The fourth direction DR4 may refer to the direction between the first direction DR1 and the second direction DR2, which be inclined from the first direction DR1 by forty-five degrees. The fifth direction DR5 may be a direction perpendicular to the fourth direction DR4.

The first emission areas EA1 and the third emission areas EA3 may be arranged in even rows. The first emission areas EA1 and the third emission areas EA3 may be arranged side by side in each of the even rows in the first direction DR1. The first emission areas EA1 and the third emission areas EA3 may be alternately arranged in each of the even rows.

The second emission areas EA2 and the fourth emission areas EA4 may be arranged in odd columns. The second emission areas EA2 and the fourth emission areas EA4 may be arranged side by side in each of the odd columns in the second direction DR2. The second emission areas EA2 and the fourth emission areas EA4 may be arranged alternately in each of the odd columns.

The first emission areas EA1 and the third emission areas EA3 may be arranged in even columns. The first emission areas EA1 and the third emission areas EA3 may be arranged side by side in each of the even columns in the second direction DR2. The first emission areas EA1 and the third emission areas EA3 may be alternately arranged in each of the even columns.

The touch detecting unit TDU may include the touch electrodes TE and RE having the driving electrodes TE and the sensing electrodes RE. The driving electrodes TE and the sensing electrodes RE are disposed in the same layer and thus they may be spaced apart from each other. That is to say, there may be a gap between adjacent ones of the driving electrodes TE and the sensing electrodes RE.

The bridge electrodes BE may be disposed in a different layer from the driving electrodes TE and the sensing electrodes RE. Each of the bridge electrodes BE may be bent at least once. The bridge electrodes BE may overlap the driving electrodes TE adjacent to one another in the second direction DR2 in the third direction DR3, which is the thickness direction of the substrate SUB. The bridge electrodes BE may overlap the sensing electrodes RE in the third direction DR3. One side of each of the bridge electrodes BE may be connected to one of the driving electrodes TE adjacent to each other in the second direction DR2 through touch contact holes TCNT1. The opposite side of each of the bridge electrodes BE may be connected to another one of the driving electrodes TE adjacent to each other in the second direction DR2 through touch contact holes TCNT1.

The driving electrodes TE and the sensing electrodes RE may be electrically separated from each other at their intersections by virtue of the bridge electrodes BE. Accordingly, mutual capacitance may be formed between the driving electrodes TE and the sensing electrodes RE.

Each of the driving electrodes TE, the sensing electrodes RE and the bridge electrodes BE may have a mesh structure or a net structure when viewed from the top. Accordingly, the driving electrodes TE, the sensing electrodes RE and the bridge electrodes BE may not overlap with the emission areas EA1, EA2, EA3 and EA4 of each of the pixels PX. Therefore, it is possible to prevent the luminance of the lights emitted from the emission areas EA1, EA2, EA3 and EA4 from being lowered, which may occur as the lights are covered by the driving electrodes TE, the sensing electrodes RE and the bridge electrodes BE.

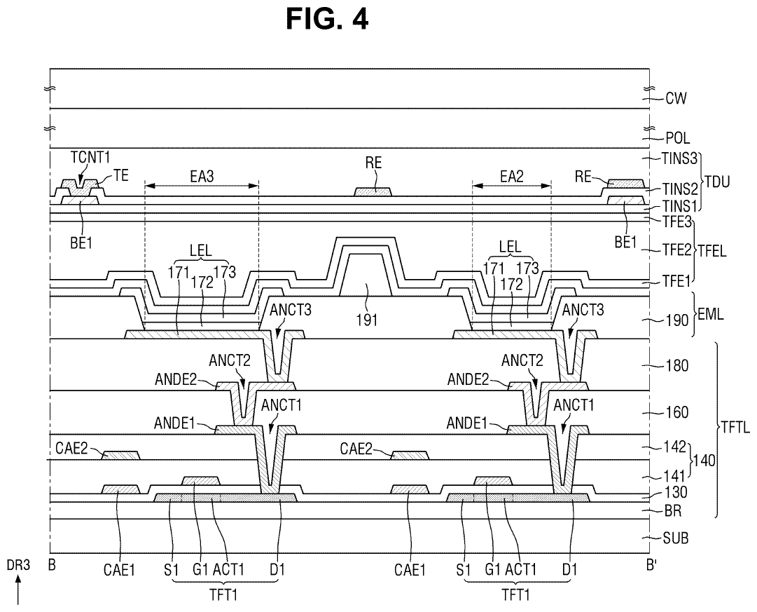

FIG. 4 is a cross-sectional view showing an embodiment of the display panel taken along line B-B′ of FIG. 3.

Referring to FIG. 4, the substrate SUB may include or consist of an insulating material such as a polymer resin. In an embodiment, the substrate SUB may include or consist of polyimide, for example. The substrate SUB may be a flexible substrate that may be bent, folded, or rolled.

The barrier film BR may be disposed on the substrate SUB. The barrier film BR is a film for protecting the thin-film transistors of the thin-film transistor layer TFTL and a light-emitting layer 172 of the emission material layer EML. The barrier film BR may be made up of multiple inorganic films stacked on one another alternately. In an embodiment, the barrier film BR may be made up of multiple layers in which one or more inorganic layers of a silicon nitride layer, a silicon oxynitride layer, a silicon oxide layer, a titanium oxide layer and an aluminum oxide layer are alternately stacked on one another, for example.

A first thin-film transistors TFT1 may be disposed on the barrier film BR. The first thin-film transistor TFT1 may include a first active layer ACT1 and a first gate electrode G1.

A first active layer ACT1 of the first thin-film transistor TFT1 may be disposed on the barrier film BR. The first active layer ACT1 of the first thin-film transistor TFT1 may include polycrystalline silicon, monocrystalline silicon, low-temperature polycrystalline silicon, amorphous silicon, or oxide semiconductor. The first active layer ACT1 may include a channel.

The first active layer ACT1 may include a first source region S1 and a first drain region D1 disposed with the channel therebetween. The channel may be an area that overlaps the first gate electrode G1 in the third direction DR3, which is the thickness direction of the substrate SUB. The first source region S1 may be disposed on one side of the first active layer ACT1, and the first drain region D1 may be disposed on the opposite side of the first active layer ACT1. The first source region S1 and the first drain region D1 may not overlap with the first gate electrode G1 in the third direction DR3. The first source region S1 and the first drain region D1 may have conductivity by doping a silicon semiconductor or an oxide semiconductor with ions or impurities.

A first gate insulator 130 may be disposed on the first active layer ACT1 of the first thin-film transistor TFT1. The first gate insulator 130 may include or consist of an inorganic layer, e.g., a silicon nitride layer, a silicon oxynitride layer, a silicon oxide layer, a titanium oxide layer, or an aluminum oxide layer.

The first gate electrode G1 of the first thin-film transistor TFT1 and a first capacitor electrode CAE1 may be disposed on the gate insulator 130. The first gate electrode G1 may overlap the first active layer ACT1 in the third direction DR3. Although the first gate electrode G1 and the first capacitor electrode CAE1 are spaced apart from each other in the example shown in FIG. 4, the first gate electrode G1 and the first capacitor electrode CAE1 may be connected with each other. The first gate electrode G1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A first inter-dielectric film 141 may be disposed on the first gate electrode G1 of the first thin-film transistor TFT1 and the first capacitor electrode CAE1. The first inter-dielectric film 141 may include or consist of an inorganic layer, e.g., a silicon nitride layer, a silicon oxynitride layer, a silicon oxide layer, a titanium oxide layer, or an aluminum oxide layer. The first inter-dielectric film 141 may include or consist of a plurality of inorganic films.

The second capacitor electrode CAE2 may be disposed on the first inter-dielectric film (also referred to as a first inter-dielectric layer) 141. The second capacitor electrode CAE2 may overlap the first capacitor electrode CAE1 of the first thin-film transistor TFT1 in the third direction DR3. When the first capacitor electrode CAE1 is connected to the first gate electrode G1, the second capacitor electrode CAE2 may overlap the first gate electrode G1 in the third direction DR3. Since the first inter-dielectric layer 141 has a predetermined dielectric constant, a capacitor may be formed by the first capacitor electrode CAE1, the second capacitor electrode CAE2 and the first inter-dielectric layer 141 disposed therebetween. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A second inter-dielectric layer 142 may be disposed over the second capacitor electrode CAE2. The second inter-dielectric layer (also referred to as a second inter-dielectric film) 142 may include or consist of an inorganic layer, e.g., a silicon nitride layer, a silicon oxynitride layer, a silicon oxide layer, a titanium oxide layer, or an aluminum oxide layer. The second inter-dielectric film 142 may include or consist of a plurality of inorganic films.

A first anode connection electrode ANDE1 may be disposed on the second inter-dielectric layer 142. The first anode connection electrode ANDE1 may be connected to the first drain electrode D1 of the first thin-film transistor TFT1 through a first connection contact hole ANCT1 that penetrates the first gate insulator 130, the first inter-dielectric film 141 and the second inter-dielectric film 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A first planarization film 160 may be disposed over the first anode connection electrode ANDE1 for providing a flat surface over level differences due to the first thin-film transistor TFT1. The first planarization film 160 may include or consist of an organic layer such as an acryl resin, an epoxy resin, a phenolic resin, a polyamide resin and a polyimide resin.

A second anode connection electrode ANDE2 may be disposed on the first planarization film (also referred to as a first planarization layer) 160. The second anode connection electrode ANDE2 may be connected to the first anode connection electrode ANDE1 through a second connection contact hole ANCT2 penetrating the first planarization layer 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

A second planarization film 180 may be disposed on the second anode connection electrode ANDE2. The second planarization film 180 may be formed as an organic layer such as an acryl resin, an epoxy resin, a phenolic resin, a polyamide resin and a polyimide resin.

Light-emitting elements LEL and a bank 190 may be disposed on the second planarization film 180. Each of the light-emitting elements LEL includes a pixel electrode 171, a light-emitting layer 172, and a common electrode 173.

The pixel electrode 171 may be disposed on the second planarization film 180. The pixel electrode 171 may be connected to the second anode connection electrode ANDE2 through a third connection contact hole ANCT3 penetrating the second planarization film 180.

In the top-emission structure in which light exits from the light-emitting layer 172 toward the common electrode 173, the pixel electrode 171 may include or consist of a metal material having a relatively high reflectivity such as a stack structure of aluminum and titanium (Ti/Al/Ti), a stack structure of aluminum and indium tin oxide (“ITO”) (ITO/Al/ITO), an APC alloy and a stack structure of APC alloy and ITO (ITO/APC/ITO). The APC alloy is an alloy of silver (Ag), palladium (Pd) and copper (Cu).

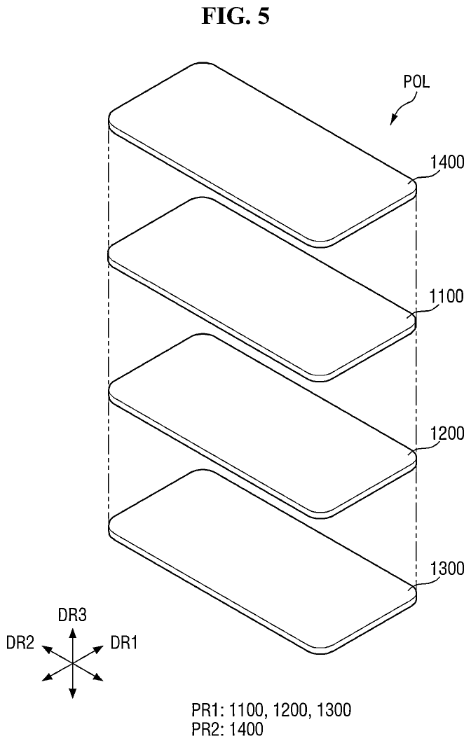

In order to define the first emission area EA1, the second emission area EA2, the third emission area EA3 and the fourth emission area EA4 in FIG. 5, the bank 190 may be formed to partition the pixel electrode 171 on the second planarization film 180. The bank 190 may be disposed to cover the edges of the pixel electrode 171. The bank 190 may include or consist of an organic layer such as an acryl resin, an epoxy resin, a phenolic resin, a polyamide resin and a polyimide resin.

In each of the first emission area EA1, the second emission area EA2, the third emission area EA3 and the fourth emission area EA4, the pixel electrode 171, the light-emitting layer 172 and the common electrode 173 are stacked on one another sequentially, so that holes from the pixel electrode 171 and electrons from the common electrode 173 are recombined in the light-emitting layer 172 to emit light.

The light-emitting layer 172 may be disposed on the pixel electrode 171 and the bank 190. The light-emitting layer 172 may include an organic material to emit light of a predetermined color. In an embodiment, the light-emitting layer 172 may include a hole transporting layer, an organic material layer, and an electron transporting layer.

The common electrode 173 may be disposed on the light-emitting layer 172. The common electrode 173 may be disposed to cover the light-emitting layer 172. The common electrode 173 may be a common layer formed commonly in the first emission area EA1, the second emission area EA2, the third emission area EA3 and the fourth emission area EA4. A capping layer may be formed on the common electrode 173.

In the top-emission organic light-emitting diode, the common electrode 173 may include or consist of a transparent conductive material (“TCP”) such as ITO and indium zinc oxide (“IZO”) that may transmit light, or a semi-transmissive conductive material such as magnesium (Mg), silver (Ag) and an alloy of magnesium (Mg) and silver (Ag). When the common electrode 173 includes or consists of a semi-transmissive conductive material, the light extraction efficiency may be increased by microcavities.

A spacer 191 may be disposed on the bank 190. The spacer 191 may support a mask during a process of fabricating the light-emitting layer (also referred to as an emission layer) 172. The spacer 191 may include or consist of an organic layer such as an acryl resin, an epoxy resin, a phenolic resin, a polyamide resin and a polyimide resin.

An encapsulation layer TFEL may be disposed on the common electrode 173. The encapsulation layer TFEL may include at least one inorganic film to prevent permeation of oxygen or moisture into the light-emitting layer 172 of the emission material layer EML. In addition, the encapsulation layer TFEL may include at least one organic film to protect the emission material layer EML from particles such as dust.

The encapsulation layer TFEL may include a first inorganic encapsulation film TFE1, an organic encapsulation film TFE2 and a second inorganic encapsulation film TFE3.

The first inorganic encapsulation film TFE1 and the second inorganic encapsulation film TFE3 may include at least one inorganic insulating material selected from the group consisting of: aluminum oxide, titanium oxide, titanium oxide, hafnium oxide, zinc oxide, silicon oxide, silicon nitride, and silicon oxy nitride. The organic encapsulation film TFE2 may include monomers. The organic encapsulation film TFE2 may be formed by applying monomers and then curing them using heat or ultraviolet light.

The touch detecting unit TDU may be disposed on the encapsulation layer TFEL. The touch detecting unit TDU may include a first touch insulating film TINS1, bridge electrodes BE1, a second touch insulating film TINS2, the driving electrodes TE, the sensing electrodes RE, and a third touch insulating film TINS3.

The first touch insulating film TINS1 may include or consist of an inorganic layer, e.g., a silicon nitride layer, a silicon oxynitride layer, a silicon oxide layer, a titanium oxide layer, or an aluminum oxide layer.

The bridge electrodes BE1 may be disposed on the first touch insulating film TINS1. The bridge electrode BE1 may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The second touch insulating film TINS2 is disposed over the bridge electrodes BE1. The second touch insulating film (also referred to as a second touch insulating layer) TINS2 may include or consist of an inorganic layer, e.g., a silicon nitride layer, a silicon oxynitride layer, a silicon oxide layer, a titanium oxide layer, or an aluminum oxide layer. In an alternative embodiment, the second touch insulating layer TINS2 may include or consist of an organic layer such as an acryl resin, an epoxy resin, a phenolic resin, a polyamide resin and a polyimide resin.

The driving electrodes TE and the sensing electrodes RE may be disposed on the second touch insulating film TINS2. The driving electrodes TE and the sensing electrodes RE may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof.

The driving electrodes TE and the sensing electrodes RE may overlap with the bridge electrodes BE1 in the third direction DR3. The driving electrodes TE may be connected to the bridge electrodes BE1 through touch contact holes TCNT1 penetrating through the first touch insulating film TINS1.

The third touch insulating film TINS3 is formed over the driving electrodes TE and the sensing electrodes RE. The third touch insulating layer TINS3 may provide a flat surface over level differences formed by the driving electrodes TE, the sensing electrodes RE and the bridge electrodes BE1. The third touch insulating film TINS3 may include or consist of an organic layer such as an acryl resin, an epoxy resin, a phenolic resin, a polyamide resin and a polyimide resin.

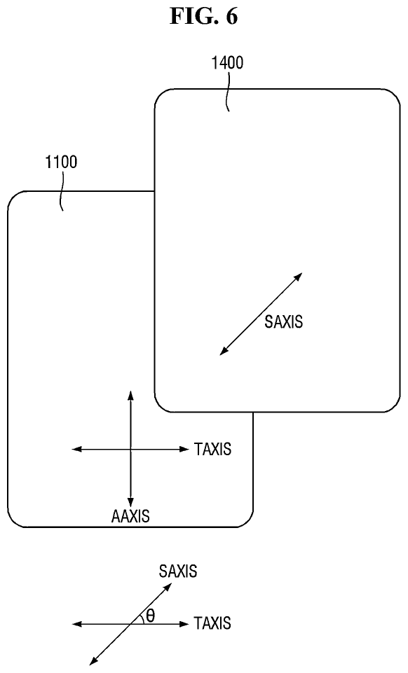

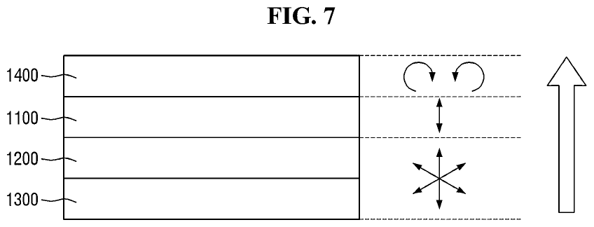

FIG. 5 is an exploded perspective view of an embodiment of the polarizing member of FIG. 4. FIG. 6 is a view showing the slow axis of the third retardation layer and the transmission axis and absorption axis of the polarizer. FIG. 7 is a cross-sectional view showing an embodiment of a polarizing member and polarization of light.

Referring to FIGS. 5 to 7, the polarizing member POL may include a first portion PR1 and a second portion PR2. The first portion PR1 serves as an anti-reflection portion to prevent the visibility of images of the display panel 100 from deteriorating due to external light. The second portion PR2 may include a sunglasses-free retarder to increase image visibility of the display panel 100 for a viewer wearing polarized sunglasses.

In order for the first portion PR1 to serve as an anti-reflection portion, the in-plane retardation value Ro of the first portion PR1 at the wavelength of approximately 550 nm may range from approximately 100 nm to approximately 180 nm. In addition, the value of Ro(450)/Ro(550) of the first portion PR1 may be equal to or less than 1.00. The value Ro(450) may be the in-plane retardation value (Ro) of the first portion PR1 at the wavelength of approximately 450 nm, and the value Ro(550) may be the in-plane retardation value (Ro) of the first portion PR1 at the wavelength of approximately 550 nm.

The first portion PR1 may include a polarizer 1100, a first retarder 1200, and a second retarder 1300. The second portion PR2 may include a third retarder 1400.

The polarizer 1100 serves to polarize the incident light into the same direction as the transmission axis TAXIS. The transmission axis TAXIS and the absorption axis AAXIS of the polarizer 1100 may intersect each other. The angle between the transmission axis TAXIS and the absorption axis AAXIS of the polarizer 1100 may be 90 degrees (°).

The polarizer 1100 may be formed by including a polarizer or a dichroic dye in a polyvinyl alcohol (PVA) resin film.

A polyvinyl alcohol resin may be obtained by saponifying a polyvinyl acetate resin. In embodiments, polyvinyl acetate resins may include polyvinyl acetate, which is a homopolymer of vinyl acetate, or a copolymer of vinyl acetate and other monomers copolymerizable therewith. In embodiments, other monomers copolymerizable with vinyl acetate may include unsaturated carboxylic acid monomers, unsaturated sulfonic acid monomers, olefin monomers, vinyl ether monomers, and acrylamide monomers having an ammonium group.

The polyvinyl alcohol resin may be a modified one, and for example, polyvinyl formal or polyvinyl acetal modified with aldehyde may be used as well. The degree of saponification of the polyvinyl alcohol resin may range from 85 mol % to 100 mol %, and preferably 98 mol % or more. The degree of polymerization of the polyvinyl alcohol resin may range approximately from 1,000 to 10,000, preferably 1,500 to 5,000.

The polyvinyl alcohol resin may be used as a raw film of the polarizer 1100. The thickness of the raw film may be approximately 10 micrometers (μm) to approximately 150 μm.

The dichroic dye may be iodine molecules or dye molecules.

The polarizer 1100 may be fabricated via a process of continuously and uniaxially orienting a polyvinyl alcohol film in an aqueous solution, a process of dyeing it with a dichroic dye to adsorbing it, a process of treating it with an aqueous boric acid solution, a water washing and drying process, etc. The polyvinyl alcohol resin film may be stretched in one direction and immersed in a solution of iodine or dichroic dye. In doing so, the iodine molecules or dichroic dye molecules are arranged in parallel in the stretching direction. Since iodine molecules and dye molecules exhibit dichroism, they may absorb light vibrating in the stretching direction and transmit light vibrating in a direction perpendicular to the stretching direction.

The first retarder 1200 may be disposed under the polarizer 1100. In an embodiment, the first retarder 1200 may be disposed on the lower surface of the polarizer 1100, for example. The first retarder 1200 is not particularly limited as long as it may prevent reflection of light incident from the outside. The first retarder 1200 may be made up of a single layer or multiple layers.

When the first retarder 1200 is made up of a single layer, the first retarder may be a half-wave (λ/2) retarder. The half-wave retarder outputs the incident light by retarding the phase of a component that vibrates in the slow axis direction by the half of a wave.

The angle between the retardation axis of the first retarder 1200 and the absorption axis AAXIS of the polarizer 1100 may be approximately 45°±α. In an embodiment, the angle α may be, but is not limited to, approximately 0.5°, for example.

The second retarder 1300 may be disposed under the polarizer 1100. In an embodiment, the second retarder 1300 may be disposed on the lower surface of the first retarder 1200, for example. The second retarder 1300 is not particularly limited as long as it may prevent reflection of light incident from the outside. The second retarder 1300 may be made up of a single layer or multiple layers.

When the second retarder 1300 is made up of a single layer, the first retarder may be a quarter-wave (λ/4) retarder. The quarter-wave retarder outputs the incident light by retarding the phase of a component that vibrates in the slow axis direction by the quarter of a wave.

The angle between the retardation axis of the second retarder 1300 and the absorption axis AAXIS of the polarizer 1100 may be, but is not limited to, approximately 10° to approximately 75°.

In another embodiment, the second retarder 1300 may be a positive C retarder. The positive C retarder may further improve image quality by improving the reflected colors in the oblique directions of a viewer side. The positive C retarder may refer to a retardation plate having an optical axis in a direction perpendicular to the plane (e.g., in the third direction DR3) and may include, e.g., a film having a refractive index ratio Nz of negative infinity, substantially −6 or less. The refractive index ratio Nz may be calculated as Equation 1 below:

$$Nz = \frac{( nx - nz )}{( nx - ny )} \qquad [ Equation 1 ]$$

where nx and ny denote the in-plane refractive indexes of the film, and nz denotes the refractive index in the thickness direction. Specifically, nx denotes the refractive index by light vibrating in the vibration direction, and ny denotes the refractive index in the direction perpendicular to nx, where x denotes the vibration direction in which the in-plane refractive index is maximum.

The positive C retarder may be fabricated by orienting a polymer film in an appropriate way, or by applying a polymerizable cholesteric liquid crystal compound to a surface of a substrate, orienting it in a predetermined direction, and then curing it. When a polymerizable cholesteric liquid crystal compound is used, a zero retardation film may be used as a substrate. The zero retardation film refers to a film with no substantial retardation even when light passes through it.

Incidentally, the third retarder 1400 may be disposed on the polarizer 1100. In an embodiment, the third retarder 1400 may be disposed on the upper surface of the polarizer 1100, for example.

As used herein, the viewer side refers to the side adjacent to the user or viewer when the polarizing member POL is attached on a surface of the display panel 100. A panel side refers to the side that is opposite to the viewer side and is adjacent to the display panel 100. Therefore, the upper surface of the polarizer 1100 and the third retarder 1400 may be disposed on the viewer side of the polarizing member POL, while the lower surface of the polarizer 1100, the first retarder 1200 and the second retarder 1300 may be disposed on the panel side of the polarizing member POL.

The third retarder 1400 may be a quarter-wave (λ/4) retarder. The quarter-wave retarder outputs the incident light by retarding the phase of a component that vibrates in the slow axis direction by the quarter of a wave. The third retarder 1400 converts the linearly polarized light that has passed through the polarizer 1100 into circularly polarized light or elliptically polarized light, so that the viewer may see images on the display panel 100 regardless of the polarization direction of the sunglasses she/he is wearing.

The angle between the slow axis SAXIS of the third retarder 1400 and the transmission axis TAXIS of the polarizer 1100 may be approximately 15° to approximately 75°. The angle θ between the slow axis SAXIS of the third retarder 1400 and the transmission axis TAXIS of the polarizer 1100 may refer to the angle between the transmission axis TAXIS of the polarizer 1100 and the slow axis SAXIS of the third retarder 1400. Since the slow axis SAXIS of the third retarder 1400 and the transmission axis TAXIS of the polarizer 1100 are defined on a plane defined by the first direction DR1 and the second direction DR2, the angle between the slow axis SAXIS of the third retarder 1400 and the transmission axis TAXIS of the polarizer 1100 may be defined on the plane defined by the first direction DR1 and the second direction DR2.

As used herein, the slow axis refers to one where the refractive index of polarized light is maximum in the plane. The retardation axis may also be also referred to as the slow axis. As used herein, the absorption axis refers to the axis that absorbs linearly polarized light. The absorption axis may be perpendicular to the transmission axis.

In this manner, the in-plane retardation value Ro of the third retarder 1400 at the wavelength of approximately 550 nm may range from approximately 37.5 nm to approximately 237.5 nm.

The in-plane retardation value Ro of the third retarder 1400 may be calculated as expressed in Equation 2 below:

$${R}_{o} = ( n x - n y ) \times d , n x \geq n y \qquad [ Equation 2 ]$$

where nx and ny denote the in-plane refractive indexes of the film, and d denotes the thickness of the film. Specifically, nx denotes the refractive index by light vibrating in the vibration direction, and ny denotes the refractive index in the direction perpendicular to nx, where x denotes the vibration direction in which the in-plane refractive index is maximum.

Each of the first retarder 1200 and the second retarder 1300 may be formed, e.g., as a film type or liquid-crystal coating layer. A film-type retarder may be obtained by orienting a polymer film in the uniaxial direction, the biaxial direction, or other appropriate ways. In an embodiment, the polymer film may include cyclic olefin polymer (“COP”), polycarbonate polymer, polyester polymer, polysulfone polymer, polyether sulfone polymer, polystyrene polymer, polyolefin polymer, polyvinyl alcohol polymer, cellulose acetate polymer, polymethyl methacrylate polymer, polyvinyl chloride polymer, polyacrylate polymer, polyamide polymer, etc., for example.

The retarder of a liquid-crystal coating layer type may be fabricated using polyimide or a reactive liquid crystal composition. In an embodiment, it may be fabricated by coating the reactive liquid crystal composition on a substrate, aligning it optically, and applying a nematic liquid crystal material to align the liquid crystal material, for example. In another embodiment, it may be fabricated by coating polyimide on a substrate, imidizing it, physically aligning it by rubbing, and then applying a nematic liquid crystal material to align the liquid crystal material.

According to the embodiment of the disclosure, each of the first retarder 1200, the second retarder 1300 and the third retarder 1400 may be formed as a liquid-crystal coating layer. In another embodiment, the second retarder 1300 and the third retarder 1400 may be formed as a liquid-crystal coating layer, and the first retarder 1200 may be formed as a film type.

According to the embodiment, as the third retarder 1400 is formed as the liquid-crystal coating layer, the thin polarizing member POL may be implemented on the polarizer in place of a thick polymer film such as cyclic olefin polymer (“COP”).

When the retarder of a liquid-crystal coating layer type includes a nematic liquid crystal material, the nematic liquid crystals may have a rod-type or a rod-shaped structure as shown in Structural Formula 1 below:

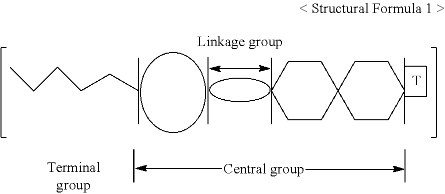

The terminal/linkage groups may affect the length and viscosity of the liquid-crystal molecules. The terminal group may be alkyl, alkoxy, alkenyl or alkenyloxy having 1 to 20 carbon atoms. The linkage group may be toluene, ester ethylene, C—C bond, OCH₂ or (CH₂)n, and n may be 1 to 20. It should be understood, however, that Structural Formula 1 is merely illustrative and the embodiments of the disclosure are not limited thereto.

In addition, in Structural Formula 1, the central group may affect the refractive index and the anisotropy of the refractive index. The central group may include, but is not limited to, one or more selected from Chemical Formulas 1 to 8 below:

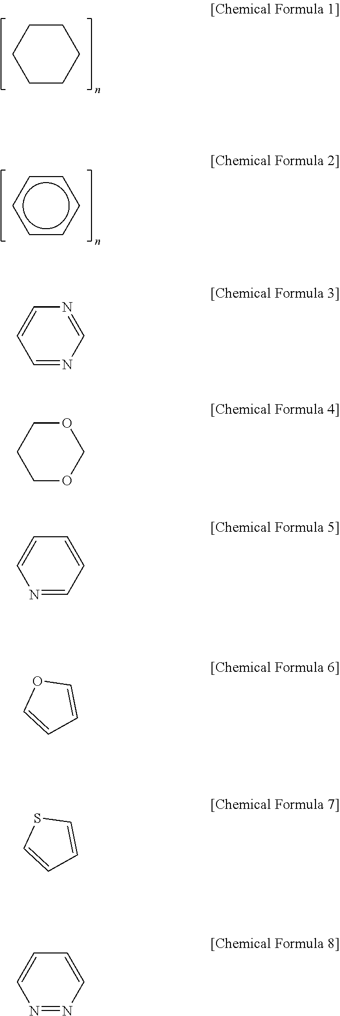

In Chemical Formulas 1 and 2, n may be 1 to 10.

In Structural Formula 1, the terminal group may affect the polarity. The terminal group may be selected from alkyl, alkoxy, CN, and halogen atoms having 1 to 20 carbon atoms.

In Structural Formula 1, the short-wavelength refractive index tends to increase depending on the aromatic ring content in the central group. Therefore, wavelength dispersion may be adjusted by appropriately adjusting the ratio of the aromatic ring of the central group and the terminal group, but this is merely illustrative.

The first retarder 1200 and the second retarder 1300 may be adhered to the polarizer 1100 and the first retarder 1200, respectively, through an adhesive. The adhesive or pressure-sensitive adhesive may be cured, but is not limited to, by ultraviolet light.

The polarizing member POL described above may be produced by separately fabricating the first portion PR1 and the second portion PR2 and then attaching them together. In an embodiment, the first retarder 1200 and the second retarder 1300 of the polarizer 1100 may be attached together, an alignment film may be coated on a substrate and aligned physically or optically, a liquid crystal material may be coated on the alignment film to form a third retarder 1400, the third retarder 1400 may be laminated on the upper surface of the polarizer 1100, and then the substrate and the alignment film may be removed, to fabricate the polarizing member POL, for example.

In another embodiment, an alignment film may be coated on the upper surface of the polarizer 1100 and aligned physically or optically, and then a liquid crystal material may be coated on the alignment film to form the third retarder 1400. Subsequently, the first retarder 1200 and the second retarder 1300 may be sequentially attached to the lower surface of the polarizer 1100, to fabricate the polarizing member POL.

As shown in FIG. 7, the light incident from the panel side to the polarizing member POL is not polarized, but may be linearly polarized by the polarizer 1100 and elliptically polarized in the third retarder 1400. Accordingly, a viewer wearing polarized sunglasses may see the images of the display device 10 that has passed through the polarizing member POL.

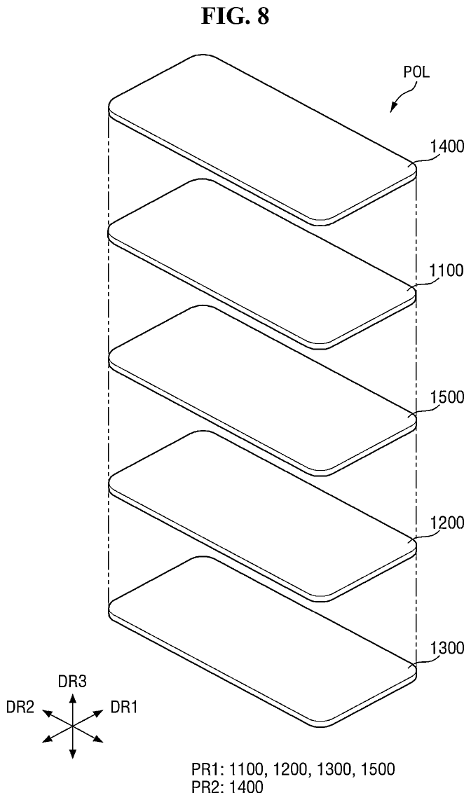

FIG. 8 is an exploded, perspective view showing another embodiment of a polarizing member.

The embodiment of FIG. 8 is different from the embodiment of FIG. 5 described above in that a first protective film 1500 is interposed between a polarizer 1100 and a first retarder 1200. In the following description, the description will focus on the difference and the redundant description will be omitted.

The polarizing member POL may include a first portion PR1 and a second portion PR2. The first portion PR1 may include a polarizer 1100, a first protective film 1500, a first retarder 1200, and a second retarder 1300. The second portion PR2 may include a third retarder 1400.

The first protective film 1500 may be disposed between the polarizer 1100 and the first retarder 1200. The first protective film 1500 may be disposed directly on the lower surface of the polarizer 1100 to protect the polarizer 1100. An adhesive may be disposed between the first protective film 1500 and the first retarder 1200. The adhesive may be cured by, but is not limited to, ultraviolet light.

The first protective film 1500 may include a resin film having excellent transparency, mechanical strength, thermal stability, moisture proof, and isotropic properties. In an embodiment, the first protective film 1500 may include an acrylic resin film such as polymethyl (meth)acrylate and polyethyl (meth)acrylate, a polyester resin film such as polyethylene terephthalate, polyethylene isophthalate, polyethylene naphthalate and polybutylene terephthalate, a cellulose resin films such as diacetyl cellulose and triacetyl cellulose, a polyolefin resin film such as polyethylene, polypropylene, polyolefin with cyclo or norbornene structures, ethylene-propylene copolymers, etc., for example.

The first protective film 1500 may further include an additive. In embodiments, such an additive may include ultraviolet absorbers, brightening agents, silica dispersants, antioxidants, pH adjusters, and leveling agents. The first protective film 1500 may be made up of a single layer or a stack of multiple layers.

According to this embodiment, the polarizing member POL may further include the first protective film 1500 to protect the polarizer 1100 and improve the reliability of the polarizing member POL.

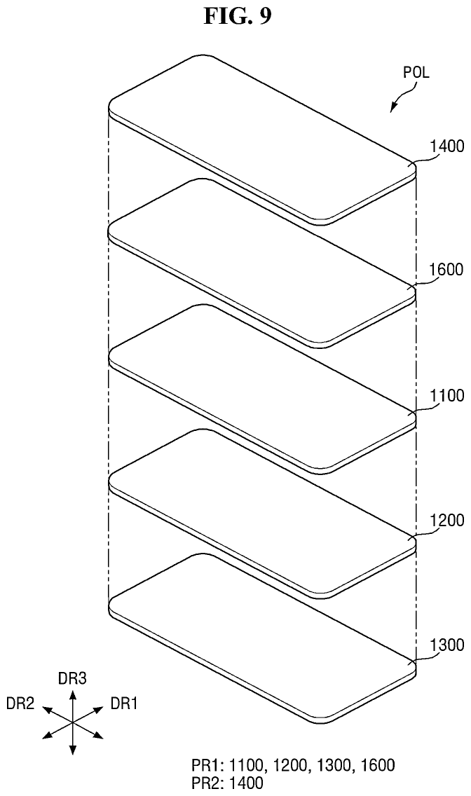

FIG. 9 is an exploded perspective view showing another embodiment of a polarizing member.

The embodiment of FIG. 9 is different from the embodiment of FIG. 5 described above in that a second protective film 1600 is interposed between a polarizer 1100 and a third retarder 1400. In the following description, the description will focus on the difference and the redundant description will be omitted.

The polarizing member POL may include a first portion PR1 and a second portion PR2. The first portion PR1 may include a polarizer 1100, a first retarder 1200, a second retarder 1300 and a second protective film 1600. The second portion PR2 may include a third retarder 1400.

The second protective film 1600 may be disposed between the polarizer 1100 and the third retarder 1400. The second protective film 1600 may be disposed directly on the upper surface of the polarizer 1100 to protect the polarizer 1100. An adhesive may be disposed between the second protective film 1600 and the third retarder 1400. The adhesive may be cured by, but is not limited to, ultraviolet light.

The second protective film 1600 may include the same material as that of the first protective film 1500 described above. The second protective film 1600 may include a resin film having excellent transparency, mechanical strength, thermal stability, moisture proof, and isotropic properties. In an embodiment, the second protective film 1600 may include an acrylic resin film such as polymethyl (meth)acrylate and polyethyl (meth)acrylate, a polyester resin film such as polyethylene terephthalate, polyethylene isophthalate, polyethylene naphthalate and polybutylene terephthalate, a cellulose resin films such as diacetyl cellulose and triacetyl cellulose, a polyolefin resin film such as polyethylene, polypropylene, polyolefin with cyclo or norbornene structures, ethylene-propylene copolymers, etc., for example.

The second protective film 1600 may further include an additive. In embodiments, such an additive may include ultraviolet absorbers, brightening agents, silica dispersants, antioxidants, pH adjusters, and leveling agents. The second protective film 1600 may be made up of a single layer or a stack of multiple layers.

According to this embodiment, the polarizing member POL may further include the second protective film 1600 to protect the upper surface of the polarizer 1100 and improve the reliability of the polarizing member POL.

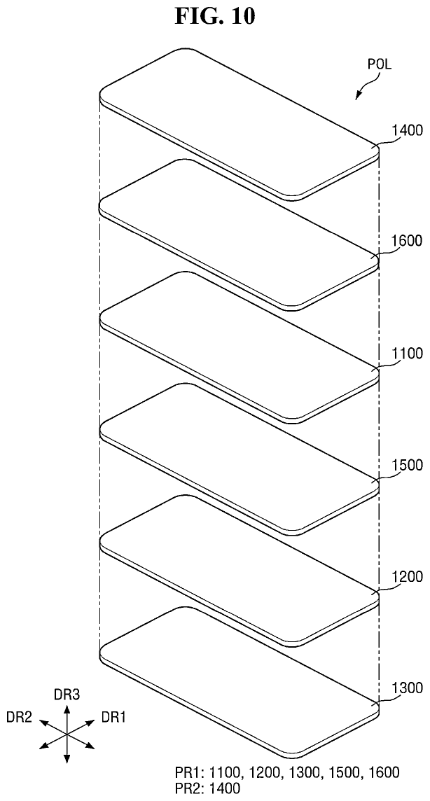

FIG. 10 is an exploded perspective view showing another embodiment of a polarizing member.

The embodiment of FIG. 10 is different from the embodiment of FIG. 5 described above a first protective film 1500 is interposed between a polarizer 1100 and a first retarder 1200, and a second protective film 1600 is interposed between the polarizer 1100 and a third retarder 1400. In the following description, the description will focus on the difference and the redundant description will be omitted.

The polarizing member POL may include a first portion PR1 and a second portion PR2. The first portion PR1 may include a polarizer 1100, a first protective film 1500, a second protective film 1600, a first retarder 1200, and a second retarder 1300. The second portion PR2 may include a third retarder 1400.

The first protective film 1500 may be disposed directly on the lower surface of the polarizer 1100 to protect the lower surface of the polarizer 1100, and the second protective film 1600 may be disposed directly on the upper surface of the polarizer 1100 to protect the upper surface of the polarizer 1100.

According to this embodiment, the polarizing member POL may further include the first protective film 1500 and the second protective film 1600 to protect the upper and lower surfaces of the polarizer 1100 and improve the reliability of the polarizing member POL.

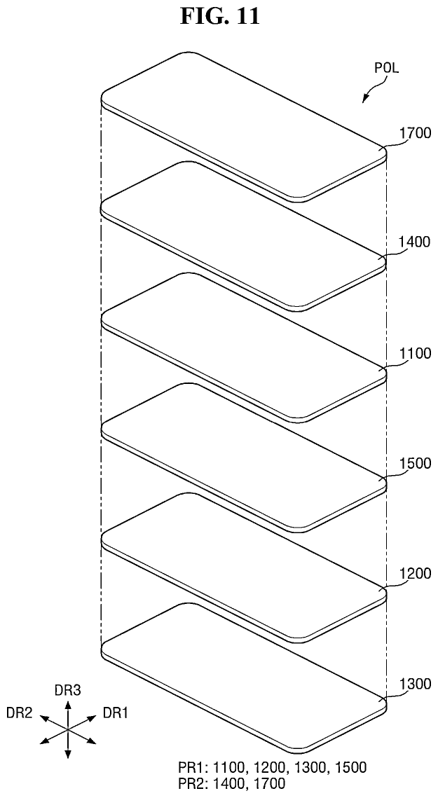

FIG. 11 is an exploded perspective view showing another embodiment of a polarizing member.

The embodiment of FIG. 11 is different from the embodiment of FIG. 8 described above in that a third protective film 1700 is disposed on a third retarder 1400. In the following description, the description will focus on the difference and the redundant description will be omitted.

The polarizing member POL may include a first portion PR1 and a second portion PR2. The first portion PR1 may include a polarizer 1100, a first protective film 1500, a first retarder 1200, and a second retarder 1300. The second portion PR2 may include a third protective film 1700 and a third retarder 1400.

The third protective film 1700 may be disposed on the third retarder 1400. The third protective film 1700 may be disposed on the third retarder 1400 to protect the polarizer 1100 from ultraviolet light included in light incident from the outside.

The third protective film 1700 may include a resin film having excellent transparency, mechanical strength, thermal stability, moisture proof, and isotropy. In an embodiment, the third protective film 1700 may include an acrylic resin film such as polymethyl (meth)acrylate and polyethyl (meth)acrylate, a polyester resin film such as polyethylene terephthalate, polyethylene isophthalate, polyethylene naphthalate and polybutylene terephthalate, a cellulose resin films such as diacetyl cellulose and triacetyl cellulose, a polyolefin resin film such as polyethylene, polypropylene, polyolefin with cyclo or norbornene structures, ethylene-propylene copolymers, etc., for example.

The third protective film 1700 may include an ultraviolet absorber in order to prevent ultraviolet light from being irradiated to the polarizer 1100. In embodiments, ultraviolet absorbers may include triazine ultraviolet absorbers, benzophenone ultraviolet absorbers, benzotriazole ultraviolet absorbers, benzoate ultraviolet absorbers, cyanoacrylate ultraviolet absorbers, etc. They may be used alone or in combination of two or more. Commercially available ultraviolet absorbers may include, e.g., Sumisorb® 340 available from Sumika Chemtex Co., Ltd., ADK STAB® LA-31 available from ADEKA Corporation, Tinuvin® 1577 available from BASF Japan Ltd; etc.

In addition, the third protective film 1700 may further include an additive. In embodiments, such an additive may include brightening agents, silica dispersants, antioxidants, pH adjusters, and leveling agents. The third protective film 1700 may be made up of a single layer or a stack of multiple layers.

An adhesive may be disposed between the third protective film 1700 and the third retarder 1400. The adhesive may be cured by, but is not limited to, ultraviolet light.

According to this embodiment, the third protective film 1700 including or consisting of an ultraviolet absorber is disposed on the polarizer 1100 and the third retarder 1400 to protect the polarizer 1100 from ultraviolet light incident from the outside.

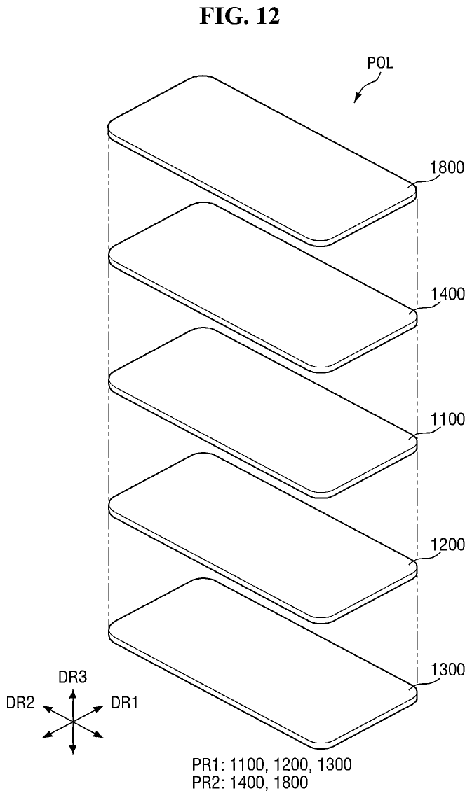

FIG. 12 is an exploded perspective view showing another embodiment of a polarizing member.

The embodiment of FIG. 12 is different from the embodiment of FIG. 5 described above in that a hard coating layer 1800 is disposed on a third retarder 1400. In the following description, the description will focus on the difference and the redundant description will be omitted.

The polarizing member POL may include a first portion PR1 and a second portion PR2. The first portion PR1 may include a polarizer 1100, a first retarder 1200, and a second retarder 1300. The second portion PR2 may include a third retarder 1400 and a hard coating layer 1800.

The hard coating layer 1800 may be disposed on the third retarder 1400. The hard coating layer 1800 may protect the polarizing member POL from external shock and directly protect the third retarder 1400. The hard coating layer 1800 may be disposed directly on the third retarder 1400.

The hard coating layer 1800 may be formed using a hard coating composition including or consisting of a light-transmitting resin, a photoinitiator, and a solvent. The hard coating composition may further include an ultraviolet absorber, inorganic oxide particles, a fluorine additive, etc.

The light-transmitting resin may be a photocurable resin. The photocurable resin may include a photocurable (meth)acrylate oligomer and/or monomer.

As photocurable (meth)acrylate oligomers, epoxy (meth)acrylate, urethane (meth)acrylate, etc. are commonly used, and urethane (meth)acrylate is preferred. Urethane (meth)acrylate may be produced by reacting (meth)acrylate having a hydroxy group in the molecule and a compound having an isocyanate group in the presence of a catalyst. In embodiments, (meth)acrylate having a hydroxy group in the molecule include: 2-hydroxyethyl (meth)acrylate; 2-hydroxyisopropyl (meth)acrylate; 4-hydroxybutyl (meth)acrylate; caprolactone ring-opened hydroxyacrylate; pentacrythritol tri(meth)acrylate; pentaerythritol tetra(meth)acrylate; dipentaerythritol penta(meth)acrylate; pentacrythritol hexa(meth)acrylate, etc. In embodiments, the compound having the isocyanate group include: 1,4-diisocyanatobutane, 1,6-diisocyanatohexane, 1,8-diisocyanatooctane, 1,12-diisocyanatododecane, 1,5-diisocyanato-2-methylpentane, trimethyl-1,6-diisocyanatohexane, 1,3-bis(isocyanatomethyl)cyclohexane, trans-1,4-cyclohexene diisocyanate, 4,4′-methylenebis(cyclohexylisocyanate), isophorone diisocyanate, toluene-2,4-diisocyanate, toluene-2,6-diisocyanate, xylene 1,4-diisocyanate, tetramethylxylene-1,3-diisocyanate, 1-chloromethyl-2,4-diisocyanate, 4,4′-methylenebis(2,6-dimethylphenylisocyanate), 4,4′-oxybis(phenylisocyanate), trifunctional isocyanate derived from hexamethylene diisocyanate, trimethane propanol adduct toluene diisocyanate, etc.

Any monomer well known in the art may be used for the monomer. Preferably, a monomer having an unsaturated group such as (meth)acryloyl group, vinyl group, styryl group and allyl group in the molecule as a photocurable functional group, and more preferably, a monomer having a (meth)acryloyl group may be used.

In embodiments, the monomer having the (meth)acryloyl group may include one or more selected from the group consisting of: neopentyl glycol acrylate, 1,6-hexane diol di(meth)acrylate, propylene glycol di(meth)acrylate, triethylene glycol di(meth)acrylate, dipropylene glycol di(meth)acrylate, polyethylene glycol di(meth)acrylate, polypropylene glycol di(meth)acrylate, trimethylolpropane tri(meth)acrylate, trimethylolethane tri(meth)acrylate, 1,2,4-cyclohexane tetra(meta) acrylate, pentaglycerol tri(meth)acrylate, pentaerythritol tetra(meth)acrylate, pentaerythritol tri(meth)acrylate, dipentacrythritol tri(meth)acrylate, dipentaerythritol penta(meth)acrylate, dipentaerythritol tetra(meth)acrylate, dipentacrythritol hexa(meth)acrylate, tripentacrythritol tri(meth)acrylate, tripentaerythritol hexa(meth)acrylate, bis(2-hydroxyethyl)isocyanurate di(meth)acrylate, hydroxyethyl (meth)acrylate, hydroxypropyl (meth)acrylate, hydroxybutyl (meth)acrylate, isooctyl (meth)acrylate, isodexyl (meth)acrylate, stearyl (meth)acrylate, tetrahydrofurfuryl (meth)acrylate, phenoxyethyl (meth)acrylate and isoborneol (meth)acrylate, etc.

The photocurable (meth)acrylate oligomer and monomer, which are the above-listed light-transmitting resins, may be used alone or in combination of two or more.

Any photoinitiator well known in the art may be used for the photoinitiator as long as it may form radicals by light irradiation. In an embodiment, a hydroxy ketone photoinitiator, an amino ketone photoinitiator, a hydrogen abstraction photoinitiator, etc. may be used, for example.

In embodiments, the photoinitiator may include 2-methyl-1-[4-(methylthio)phenyl]2-morpholine propanone-1, diphenyl ketone, benzyl dimethyl ketal, 2-hydroxy-2-methyl-1-phenyl-1-one, 2,2-dimethoxy-2-phenyl-acetophenone, anthraquinone, fluorene, triphenylamine, carbazole, 3-methylacetophenone, 4-chloroacetophenone, 4,4-dimethoxyacetophenone, 4,4-diaminobenzophenone, 1-hydroxycyclohexylphenyl ketone, benzophenone, diphenyl(2,4,6-trimethylbenzoyl)phosphine oxide, etc. The above-listed photoinitiators may be used alone or in combination of two or more.

Any solvent well known in the art may be used for the solvent. Specifically, alcohol solvent (methanol, ethanol, isopropanol, butanol, methyl cellosolve, ethyl cellosolve, etc.); ketone solvent (methyl ethyl ketone, methyl butyl ketone, methyl isobutyl ketone, diethyl ketone, dipropyl ketone, cyclohexanone, etc.); acetate solvent (ethyl acetate, propyl acetate, normal butyl acetate, tertiary butyl acetate, methyl cellosolve acetate, ethyl cellosolve acetate, propylene glycol monomethyl ether acetate, propylene glycol monoethyl ether acetate, propylene glycol monopropyl ether acetate, methoxybutyl acetate, methoxypentyl acetate, etc.); hexane solvent (hexane, heptane, octane, etc.); benzene solvent (benzene, toluene, xylene, etc.); ether solvent (diethylene glycol dimethyl ether, diethylene glycol diethyl ether, diethylene glycol dipropyl ether, diethylene glycol dibutyl ether, propylene glycol monomethyl ether, etc.) may be used. The above-listed solvents may be used alone or in combination of two or more.

The thickness of the hard coating layer 1800 may be approximately 3 μm to approximately 20 μm, specifically approximately 3 μm to approximately 15 μm. As the hard coating layer 1800 has a thickness within the above range, excellent surface hardness, case of handling, and flexibility may be achieved.

The method of applying the hard coating composition is not particularly limited. Any method well known in the art may be employed. In an embodiment, the hard coating composition may be applied by bar coating, knife coating, roll coating, blade coating, die coating, micro gravure coating, comma coating, slot die coating, lip coating, solution casting, etc., for example.

According to this embodiment, the polarizing member POL may be protected from external shock by disposing the hard coating layer 1800 on the third retarder 1400.

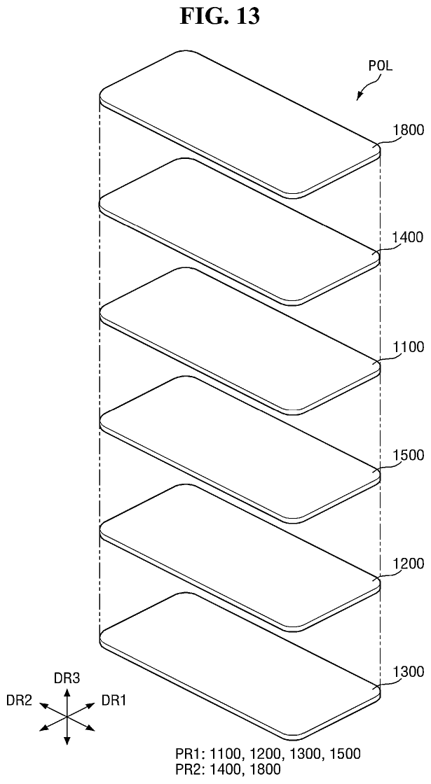

FIG. 13 is an exploded perspective view showing another embodiment of a polarizing member.

The embodiment of FIG. 13 is different from the embodiment of FIG. 12 described above in that a first protective film 1500 is interposed between a polarizer 1100 and a first retarder 1200. In the following description, the description will focus on the difference and the redundant description will be omitted.

The polarizing member POL may include a first portion PR1 and a second portion PR2. The first portion PR1 may include a polarizer 1100, a first protective film 1500, a first retarder 1200, and a second retarder 1300. The second portion PR2 may include a third retarder 1400, a third protective film 1700 and a hard coating layer 1800. The first protective film 1500 has been described above in detail in FIG. 8, and thus will be described briefly.

The first protective film 1500 may be disposed between the polarizer 1100 and the first retarder 1200. The first protective film 1500 may be disposed directly on the lower surface of the polarizer 1100 to protect the polarizer 1100. An adhesive may be disposed between the first protective film 1500 and the first retarder 1200. The adhesive may be cured by, but is not limited to, ultraviolet light.

According to this embodiment, the polarizing member POL may further include the first protective film 1500 to protect the polarizer 1100 and improve the reliability of the polarizing member POL.

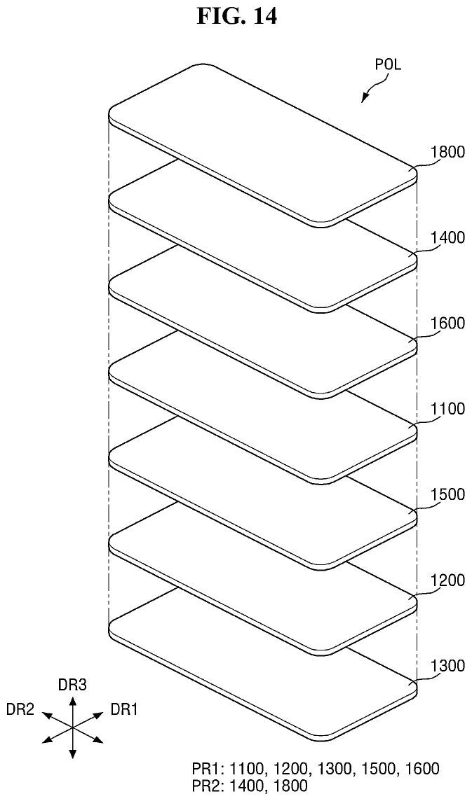

FIG. 14 is an exploded perspective view showing another embodiment of a polarizing member.

The embodiment of FIG. 14 is different from the embodiment of FIG. 13 described above in that a second protective film 1600 is interposed between a polarizer 1100 and a third retarder 1400. In the following description, the description will focus on the difference and the redundant description will be omitted.

The polarizing member POL may include a first portion PR1 and a second portion PR2. The first portion PR1 may include a polarizer 1100, a first protective film 1500, a second protective film 1600, a first retarder 1200, and a second retarder 1300. The second portion PR2 may include a third retarder 1400 and a hard coating layer 1800. The second protective film 1600 has been described above in detail in FIG. 9, and thus will be described briefly.

The second protective film 1600 may be disposed between the polarizer 1100 and the third retarder 1400. The second protective film 1600 may be disposed directly on the upper surface of the polarizer 1100 to protect the polarizer 1100. An adhesive may be disposed between the second protective film 1600 and the third retarder 1400. The adhesive may be cured by, but is not limited to, ultraviolet light.

According to this embodiment, the polarizing member POL may further include the second protective film 1600 to protect the upper surface as well as the lower surface of the polarizer 1100 and improve the reliability of the polarizing member POL.

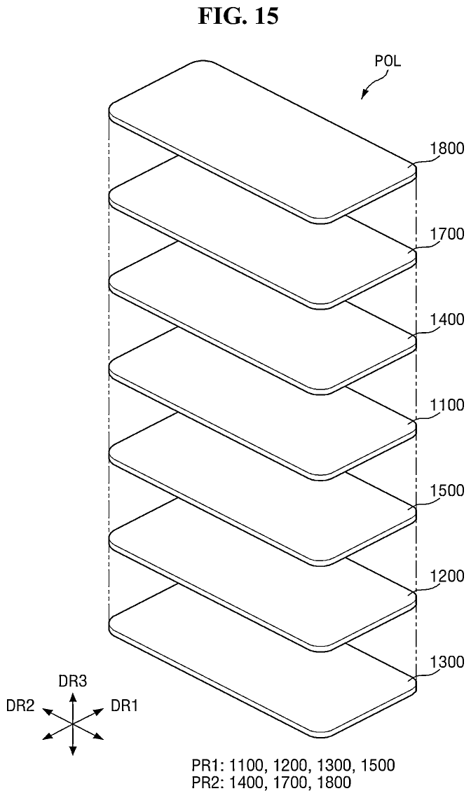

FIG. 15 is an exploded perspective view showing another embodiment of a polarizing member.

The embodiment of FIG. 15 is different from the embodiment of FIG. 11 described above in that a hard coating layer 1800 is further disposed on a third protective film 1700. In the following description, the description will focus on the difference and the redundant description will be omitted.

The polarizing member POL may include a first portion PR1 and a second portion PR2. The first portion PR1 may include a polarizer 1100, a first protective film 1500, a first retarder 1200, and a second retarder 1300. The second portion PR2 may include a third retarder 1400, a third protective film 1700 and a hard coating layer 1800. The hard coating layer 1800 has been described above in detail in FIG. 12, and thus will be described briefly.

The hard coating layer 1800 may be disposed on the third protective film 1700. In an embodiment, the hard coating layer 1800 may be disposed directly on the upper surface of the third protective film 1700, for example. The hard coating layer 1800 may protect the polarizing member POL from external shock.

According to this embodiment, the polarizing member POL may be protected from external shock by disposing the hard coating layer 1800 on the third protective film 1700.

The polarizing member POL shown in FIGS. 5 to 15 described above may be applied to an organic light-emitting display device using organic light-emitting diodes; a quantum-dot light-emitting display device including a quantum-dot light-emitting layer; an inorganic light-emitting display device including an inorganic semiconductor; a micro light-emitting display device using micro or nano light-emitting diodes (micro LEDs or nano LEDs); and a liquid-crystal display device including a liquid-crystal layer, a plasma display device, an electroluminescence display device, etc.

While the invention is susceptible to various modifications and alternative forms, illustrative embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the invention as defined by the appended claims.

### Example: Fabrication of Polarizing Member of FIG. 8

A transparent unstretched polyvinyl alcohol film (PE60 available from Kuraray Co. Ltd) with a degree of saponification of 99.9% or more was swelled by immersing it in water (deionized water) at 30 degrees Celsius (° C.) for 2 minutes, and then was dyed by immersing it at 30° C. for 4 minutes in a dyeing solution containing 1.25 millimoles per liter (mM/L) of iodine, 1.25% by weight of potassium iodide, and 0.0005% by weight of nitric acid. Specifically, in the swelling and dyeing steps, it was stretched at a stretching ratio of 1.3 times and 1.4 times, respectively, so that the cumulative stretching ratio up to the dyeing bath was 1.82 times.

Subsequently, it was crosslinked by immersing it at 50° C. for 30 seconds in an aqueous solution for crosslinking that contains 10% by weight of potassium iodide and 3.7% by weight of boric acid (first crosslinking), and was stretched at the stretching ratio of 2 times. Subsequently, it was crosslinked by immersing it at 50° C. for 20 seconds in an aqueous solution for crosslinking that contains 10% by weight of potassium iodide and 3.7% by weight of boric acid (second cross-linking), and was stretched at the stretching ratio of 1.5 times (the cumulative stretching ratio of the first and second crosslinking is 3 times). The total cumulative stretching ratio of the swelling, dyeing and crosslinking steps was set to 5.46 times. The crosslinked polyvinyl alcohol film was dried in an oven at 70° C. for 4 minutes to prepare a polarizer 1100.

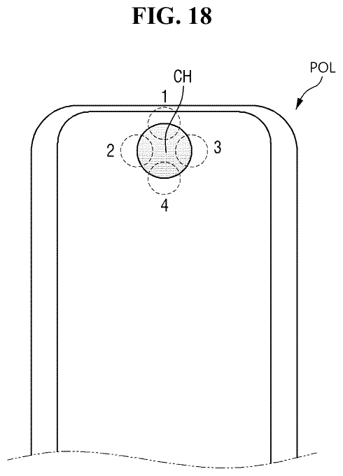

The first protective film 1500 was attached to the lower surface of the polarizer 1100 using an adhesive, and the first retarder layer 1200 and the second retarder layer 1300 were attached to the lower surface of the first protective film 1500 using an adhesive. Subsequently, an alignment film was applied on the substrate and irradiated with ultraviolet light to photo-align the alignment film. Nematic liquid crystals were applied on the alignment film and cured by irradiating ultraviolet light to prepare the third retarder 1400. Next, the third retarder 1400 was laminated on the upper surface of the polarizer 1100, and the substrate and the alignment film were delaminated together, to fabricate the polarizing member. In this manner, the polarizing member POL shown in FIG. 8 was fabricated, which consists of the third retarder 1400, the polarizer 1100, the first protective film 1500, the first retarder 1200 and the second retarder 1300 from top to bottom. Subsequently, a camera hole CH (refer to FIG. 18) was formed in the polarizing member POL using a laser. In doing so, the angle between the retardation axis of the third retarder 1400 and the transmission axis of the polarizer 1100 was 45 degrees, and the polarizing member POL was fabricated to have the retardation of 137.5 nm.

### EMBODIMENTS

### Embodiment 1 and Embodiment 2

The liquid crystals of the third retarder were produced as different rod-types of liquid crystals in the nematic liquid crystals.

### Comparative Example

The liquid crystals of the third retarder were produced as disk-type liquid crystals in the nematic liquid crystals.

### Experimental Example

### Reliability Evaluation of Polarizing Members

Reliability evaluation was performed on the polarizing members fabricated according to Embodiments 1 and 2 and Comparative Example.

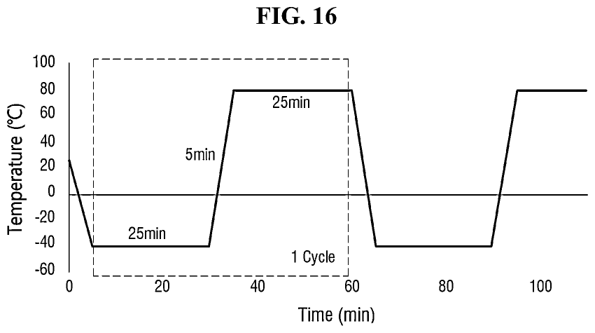

FIG. 16 is a graph showing temperature change over time as conditions for reliability evaluation.

The reliability evaluation was conducted up to 500 cycles, in each cycle the polarizing member was exposed at −40° for 25 minutes, the temperature was increased to 80° for 5 minutes, and then it was exposed at 80° for 25 minutes, as shown in FIG. 16.

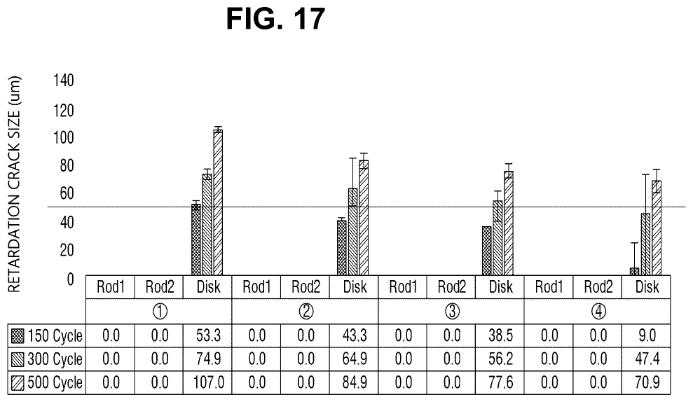

FIG. 17 is a graph showing results of reliability evaluation on the polarizing members. FIG. 18 is a view showing locations where cracks in third retarders of the polarizing members were observed.

In FIG. 17, Rod1 shown on the horizontal axis represents Embodiment 1, Rod2 represents Embodiment 2, and Disk represents a polarizing member according to Comparative Example. The symbols \textcircled{1}, \textcircled{2}, \textcircled{3} and \textcircled{4} represent the numbers of different samples fabricated under the same conditions as Embodiments 1 and 2 and Comparative Example. Specifically, four polarizing film samples were prepared under the same conditions as Embodiments 1 and 2, and Comparative Example, and reliability evaluation was performed on each of them. The retardation crack size on the vertical axis represents the length of cracks occurred in the third retarders.

Cracks in the third retarders of the polarizing members POL were observed on the upper side 1, the left side 2, the right side 3 and the lower side 4 of a camera hole CH, as shown in FIG. 18.

Referring to FIG. 17, in the polarization members using rod-type liquid crystals in nematic liquid crystals used in the third retarders according to Embodiments 1 and 2, no crack occurred in the third retarders during the reliability evaluations for 150, 300 and 500 cycles. On the contrary, in the polarization member using disk-type liquid crystals in nematic liquid crystals used in the third retarder according to Comparative Example, cracks occurred in the third retarder at 150 cycles, and the crack size gradually increased with cycles.

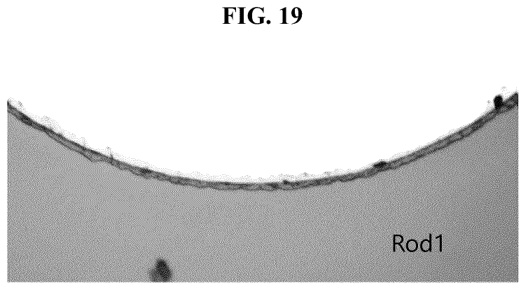

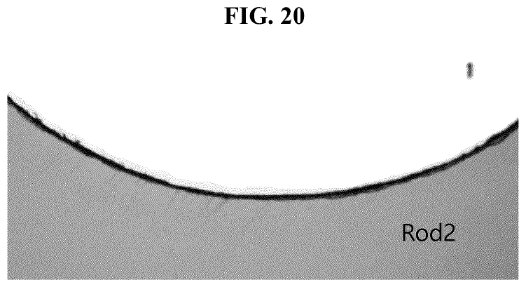

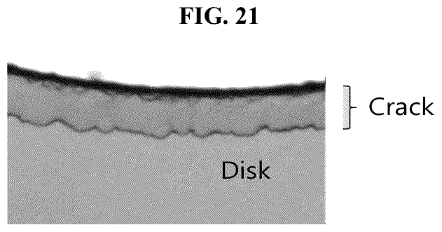

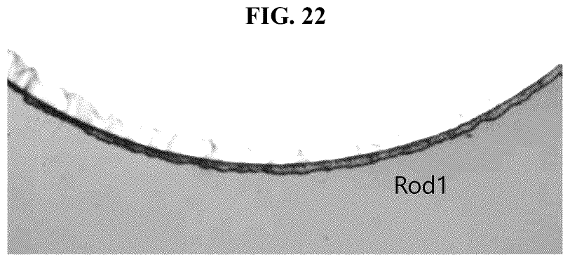

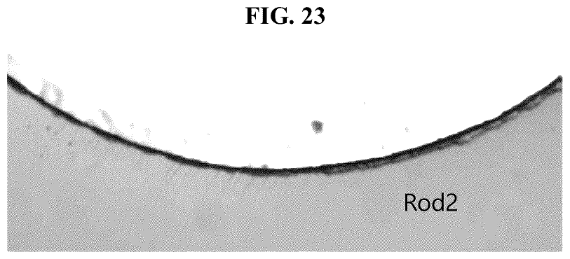

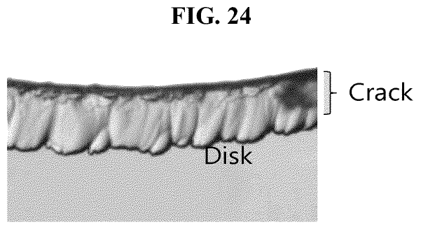

FIG. 19 is an optical image of the camera hole after 150 cycles of reliability evaluation were conducted in the polarizing member according to Embodiment 1. FIG. 20 is an optical image of the camera hole after 150 cycles of reliability evaluation were conducted in the polarizing member according to Embodiment 2. FIG. 21 is an optical image of the camera hole after 150 cycles of reliability evaluation were conducted in the polarizing member according to Comparative Example. FIG. 22 is an optical image of the camera hole after 500 cycles of reliability evaluation were conducted in the polarizing member according to Embodiment 1. FIG. 23 is an optical image of the camera hole after 500 cycles of reliability evaluation were conducted in the polarizing member according to Embodiment 2. FIG. 24 is an optical image of the camera hole after 500 cycles of reliability evaluation were conducted in the polarizing member according to Comparative Example.

Referring to FIGS. 19 to 21, at the camera hole of each polarizing member after 150 cycles of reliability evaluation was conducted, it may be seen that no crack occurred in Examples 1 and 2 whereas cracks occurred in the Comparative Example.

Referring to FIGS. 22 to 24, at the camera hole of each polarizing member after 500 cycles of reliability evaluation was conducted, it may be seen that no crack occurred in Examples 1 and 2 whereas cracks occurred in the Comparative Example.

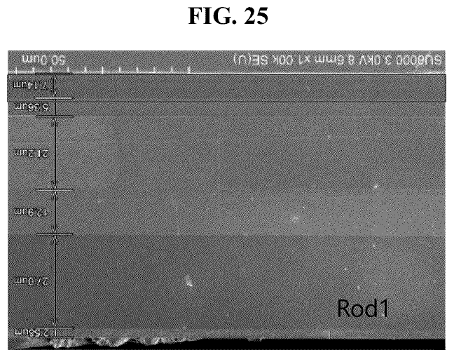

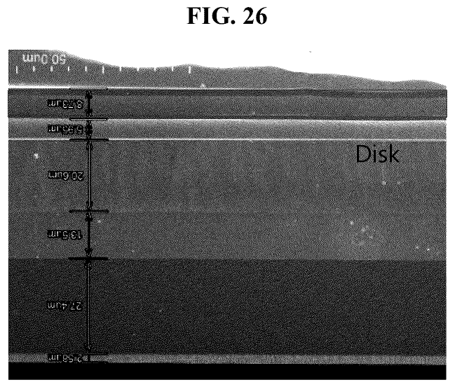

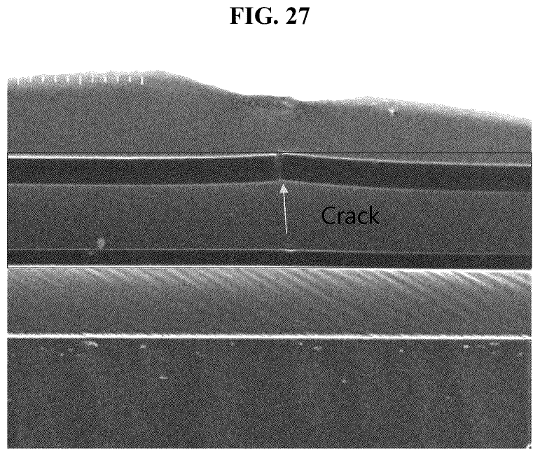

FIG. 25 is a scanning electron microscope (“SEM”) image of the camera hole after 500 cycles of reliability evaluation were conducted in the polarizing member according to Embodiment 1. FIG. 26 is an SEM image of the camera hole after 500 cycles of reliability evaluation were conducted in the polarizing member according to Comparative Example. FIG. 27 is an enlarged image of the image of FIG. 26.

Referring to FIG. 25, it may be seen from the SEM image showing the cross section of the camera hole of the polarizing member after 500 cycles of reliability evaluation were conducted that no crack occurred in the third retarder according to Embodiment 1, whereas cracks occurred in Comparative Example.

It may be seen from the above results that the third retarder including or consisting of rod-type liquid crystals in the nematic liquid crystals on the polarizer has no crack and thus exhibits excellent reliability, while the third retarder including or consisting of disk-type liquid crystals has cracks and thus the reliability evaluation is not satisfactory. In view of the above, the third retarder according to the disclosure may provide a highly reliable polarizing member by including rod-type liquid crystals in nematic liquid crystals.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A polarizing member comprising:
a polarizer including an absorption axis and a transmission axis which intersect each other;
a first retarder disposed under the polarizer;
a second retarder disposed under the first retarder; and
a third retarder disposed on the polarizer,
wherein an in-plane retardation value of the third retarder ranges from approximately 37.5 nanometers to approximately 237.5 nanometers, and
wherein an angle between a retardation axis of the third retarder and the transmission axis of the polarizer ranges from approximately 15 degrees to approximately 75 degrees.

2. The polarizing member of claim 1, wherein the third retarder comprises nematic liquid crystals of a rod shape.

3. The polarizing member of claim 1, wherein the third retarder comprises a λ/4 retarder.

4. The polarizing member of claim 1, wherein the first retarder comprises a λ/2 retarder, and the second retarder comprises a λ/4 retarder.

5. The polarizing member of claim 1, wherein the first retarder comprises a λ/2 retarder, and the second retarder comprises a positive C-plate.

6. The polarizing member of claim 1, further comprising:
a first protective film disposed between the polarizer and the first retarder,
wherein the first protective film comprises an acrylic resin film, a polyester resin film, a cellulose resin film, or a polyolefin resin film.

7. The polarizing member of claim 6, further comprising:
a second protective film disposed between the polarizer and the third retarder.

8. The polarizing member of claim 1, further comprising:
a protective film disposed on the third retarder.

9. The polarizing member of claim 8, further comprising:
a hard coating layer disposed on the protective film, wherein the hard coating layer comprises (meth)acrylate.

10. The polarizing member of claim 1, further comprising:
a first protective film disposed between the polarizer and the third retarder,
wherein the first protective film comprises an acrylic resin film, a polyester resin film, a cellulose resin film, or a polyolefin resin film.

11. The polarizing member of claim 1, further comprising:
a hard coating layer disposed on the third retarder, wherein the hard coating layer comprises (meth)acrylate.

12. The polarizing member of claim 11, further comprising:
a first protective film disposed between the polarizer and the first retarder,
wherein the first protective film comprises an acrylic resin film, a polyester resin film, a cellulose resin film, or a polyolefin resin film.

13. The polarizing member of claim 12, further comprising:
a second protective film disposed between the polarizer and the third retarder.

14. A display device comprising:
a display panel; and
a polarizing member disposed on the display panel, the polarizing member comprising:
a polarizer having an absorption axis and a transmission axis which intersect each other;
a first retarder disposed under the polarizer;
a second retarder disposed under the first retarder; and
a third retarder disposed on the polarizer,
wherein an in-plane retardation value of the third retarder ranges from approximately 37.5 nanometers to approximately 237.5 nanometers, and
wherein an angle between a retardation axis of the third retarder and the transmission axis of the polarizer ranges from approximately 15 degrees to approximately 75 degrees.

15. The display device of claim 14, wherein the display panel comprises:
a pixel electrode disposed on a substrate;
a light-emitting layer disposed on the pixel electrode; and
a common electrode disposed on the light-emitting layer.

16. The display device of claim 15, wherein the display panel comprises:
an encapsulation layer disposed on the common electrode; and
a touch sensor disposed on the encapsulation layer.

17. The display device of claim 16, further comprising:
a cover window disposed on the polarizing member.

18. The display device of claim 14, wherein the third retarder comprises nematic liquid crystals of a rod shape.

19. The display device of claim 14, wherein the third retarder comprises a λ/4 retarder.

20. The display device of claim 14, wherein the first retarder comprises a λ/2 retarder, and the second retarder comprises a 24 retarder.
